(19) United States
(12) Patent Application Publication
(10) Pub. No.: US 2008/0128717 A1
(43) Pub. Date: Jun. 5, 2008

(54) Light emitting diode package and backlight unit having the same

(76) Inventors: Hyeon-Yong Jang, Osan-si (KR); Hyung-Ku Kang, Seoul (KR); Sang-Hoon Park, Yongin-si (KR); Woo Young Lee, Suseong-gu (KR)

Correspondence Address: MACPHERSON KWOK CHEN & HEID LLP, 2033 GATEWAY PLACE, SUITE 400, SAN JOSE, CA, 95110, US

(21) Appl. No.: 11/982,237

(22) Filed: Oct. 31, 2007

(30) Foreign Application Priority Data
Nov. 6, 2006 (KR) 10-2006-0108807

(51) Int. Cl. H01L 33/00

(52) U.S. Cl. 257/88; 257/E33.058

(57) ABSTRACT

A light-emitting diode (“LED”) package and a backlight unit having the same are disclosed. The LED package includes a package substrate, at least two LED chips arranged on the package substrate spaced apart from each other and having different brightness characteristics, a plurality of electrodes mounted on the package substrate to supply electrical power to the LED chips, and electric wires connecting the electrodes to the LED chips.

### CROSS-REFERENCE TO RELATED APPLICATIONS

This application claims priority of Korea Patent Application No. 10-2006-108807, filed Nov. 6, 2006, the entire disclosure of which is incorporated herein by reference.

### BACKGROUND OF THE INVENTION

1. Field of the Invention

The present invention relates to a light emitting diode (“LED”) package and a backlight unit having the same.

2. Description of the Related Art

Generally, flat panel display devices are classified into self-emissive and non-emissive devices. Self-emissive devices include electroluminescent (“EL”) devices and a plasma display panel (“PDP”), whereas the non-emissive devices include a liquid crystal display (“LCD”) device.

The LCD device does not emit light by itself and needs external light to display an image. Accordingly, the LCD device has a backlight unit to supply light.

Typical light sources used in the backlight unit include a cold cathode fluorescent lamp (“CCFL”), an external electrode fluorescent lamp (“EEFL”), and a light emitting diode (“LED”). Of these, the LED type has a faster response time compared to the CCFL and the EEFL, and also is known as an environment-friendly device because it is a solid state component which does not contain heavy metal. Thus, demand for the LED device has increased in various industry fields.

A backlight unit having an LED chip as a light source is typically fabricated by following processes. First, LEDs are processed on a wafer, and then the wafer is cut into pieces to fabricate LED chips. The fabricated LED chips are subject to a brightness and wavelength characteristic test. Only the LEDs which are in a certain characteristic range are selected as good quality products and are mounted on a package substrate, thereby completing an LED package. A plurality of LED packages is mounted on a circuit board at regular intervals, thereby completing a backlight unit.

The procedure for testing and selecting the fabricated LED chips is typically as follows. First, brightness of the LED chips is tested. A brightness test result of a plurality of LED chips can be represented by a normal distribution curve illustrated in FIG. 1 which shows a relationship between brightness and the number of LED chips. In FIG. 1, the vertical axis denotes the number of LED chips, and the horizontal axis denotes brightness of the LED chips. As shown in FIG. 1, the number of LED chips is symmetrically distributed centering on a mean brightness value (m_{L}), and most LED chips have a brightness equal to or close to the mean value (m_{L}). LED chips which are in a certain range (d1) around the mean brightness value (m_{L}) are selected as good quality products. A brightness deviation of the LED chips selected as the good quality products to obtain a uniform light emitting value in the backlight unit is within, for example, around 50 candela (cd), and therefore the LED chips selected for the backlight unit have a uniform brightness characteristic. An LED package having such LED chips provides a uniform brightness characteristic.

The LED chips selected as the good quality products in the brightness test further undergo a wavelength test. The wavelength test result of a plurality of LED chips can be represented by a normal distribution curve as illustrated in FIG. 2 which shows a relationship between wavelength and the number of LED chips. As shown in FIG. 2, the number of LED chips is symmetrically distributed centering on a mean wavelength value (m_{W}), and typically most LED chips have a wavelength equal or close to the mean value (m_{W}). LED chips which are in a certain range (d2) around the mean wavelength value (m_{W}) are selected as good quality products.

However, among the LED chips which have undergone these tests, a ratio of the LED chips selected as a good quality product is very low. Thus, since a large number of LED chips are not used, the manufacturing yield is low and accordingly the manufacturing cost of usable LED chips is high.

### SUMMARY OF THE INVENTION

The present invention provides an LED package in which a plurality of LED chips having different characteristics are mounted on one package substrate to increase a manufacturing yield, and a backlight unit having the LED package.

In accordance with one aspect of the present invention, a light-emitting diode (“LED”) package comprises a substrate, at least two LED chips arranged on the substrate in a spaced apart relationship, the at least two chips having different brightness characteristics, a plurality of electrode terminals mounted on the substrate to supply electrical power to the at least two LED chips, and electrical conductors connecting the electrode terminals to the at least two LED chips.

The at least two LED chips emit the same color light.

The at least two LED chips comprise a first LED chip having a brightness greater than a mean brightness value, and a second LED chip having a brightness less than the mean brightness value.

The plurality of electrode terminals includes first, second, third and fourth terminals, and the electrical conductors include first, second, third and fourth electrical conductors, the first and second electrode terminals are coupled to the first and second electrical conductors for supplying electrical power to one of the at least two LED chips, and the third and fourth electrode terminals are coupled to the third and fourth electrical conductors for supplying electrical power to the other LED chip.

The at least one of the first and second electrode terminals associated with one of the first and second LED chips has an extending portion which extends such that it insulatedly crosses a path of an electrical conductor connected to the other one of the LED chips.

The LED package further comprises a passivation member arranged on the substrate to cover the LED chips.

The passivation member is made of a light transmitting material.

The passivation member is made of an illuminant material.

The passivation member is made of the illuminant material generating a different color from a color of light generated from the LED chips.

In accordance with another aspect of the present invention, a backlight unit comprises a circuit board having formed thereon first and second electrical conductors, and a plurality of light-emitting diode (“LED”) packages mounted on the circuit board, and each electrically connected to the first and second electrical conductors, each LED package comprising, a substrate, at least two LED chips mounted on the substrate in a spaced apart relationship, the at least two chips having different brightness characteristics, a plurality of electrode terminals mounted on the substrate to supply electrical power to the at least two LED chips, and electrical conductors connecting the electrode terminals to the at least two LED chips.

The at least two LED chips emit the same color light.

The at least two LED chips comprise, a first LED chip having a brightness greater than a mean brightness value; and a second LED chip having a brightness less than the mean brightness value.

The plurality of electrode terminals includes first, second, third and fourth terminals, and the electrical conductors include first, second, third and fourth electrical conductors, the first and second electrode terminals are coupled to the first and second electrical conductors for supplying electrical power to one of the at least two LED chips, and the third and fourth electrode terminals are coupled to the third and fourth electrical conductors for supplying electrical power to the other LED chip.

The at least one of the first and second electrode terminals associated with one of the first and second LED chips has an extending portion which extends such that it insulatedly crosses a path of an electrical conductor connected to the other one of the LED chips.

The backlight unit further comprises a passivation member arranged on the package substrate to cover the LED chips.

The passivation member is made of an illuminant material generating a different color from a color of light generated from the LED chips.

The backlight unit further comprises a heat slug positioned between at least one LED package substrate and the circuit board.

The backlight unit further comprises a heat sink positioned on a side of the circuit board opposite the side of the circuit board on which the LED packages are positioned.

The ends of the first and second electrical conductors are commonly connected at a node.

The backlight unit further comprises a current detecting resistor electrically connected to the node.

### BRIEF DESCRIPTION OF THE DRAWINGS

The above and other features and advantages of the present invention will be more apparent from the following detailed description in conjunction with the accompanying drawings, in which:

FIG. 1 is a curve illustrating a relationship between brightness and the number of LED chips;

FIG. 2 is a curve illustrating a relationship between a wavelength of light and the number of LED chips;

FIG. 3 is a plan view illustrating an LED package in accordance with a first exemplary embodiment of the present invention;

FIG. 4 is a cross-sectional view taken along line I-I′ of FIG. 3;

FIG. 5 is a plan view illustrating an LED package having a modified extending portion in accordance with an exemplary second embodiment of the present invention;

FIG. 6 is a plan view illustrating an LED package in which three LED chips are mounted on one package substrate in accordance with a third exemplary embodiment of the present invention;

FIG. 7 is a plan view illustrating an LED package in which four LED chips are mounted on one package substrate in accordance with a fourth exemplary embodiment of the present invention;

FIG. 8 is a plan view illustrating a backlight unit in accordance with an exemplary fifth embodiment of the present invention;

FIG. 9 is a cross-sectional view taken along line II-II′ of FIG. 8;

FIG. 10 is a circuit diagram illustrating a backlight unit in accordance with a sixth exemplary embodiment of the present invention; and

FIG. 11 is a curve illustrating a brightness range of LED chips used for the LED package in accordance with an exemplary seventh embodiment of the present invention.

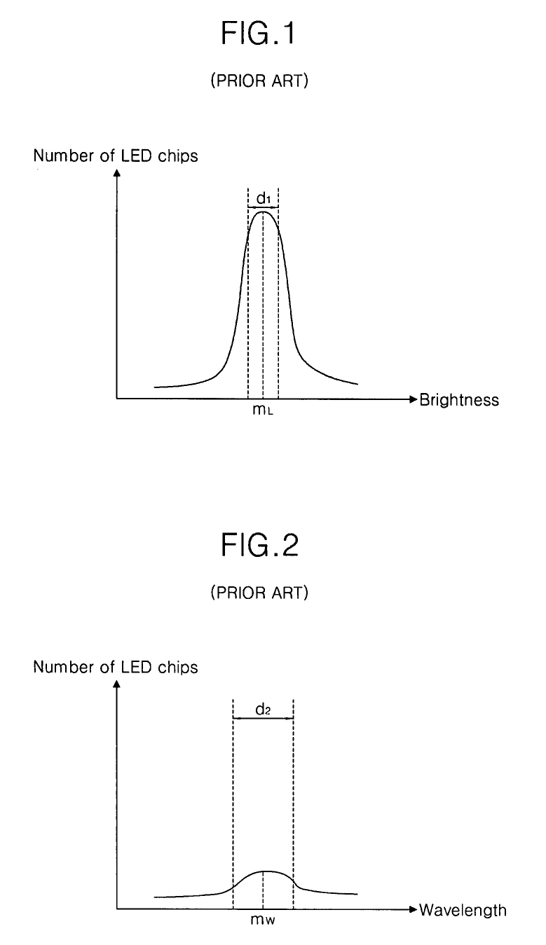

### DETAILED DESCRIPTION OF THE INVENTION

The exemplary embodiments of the present invention are described below with reference to the attached drawings.

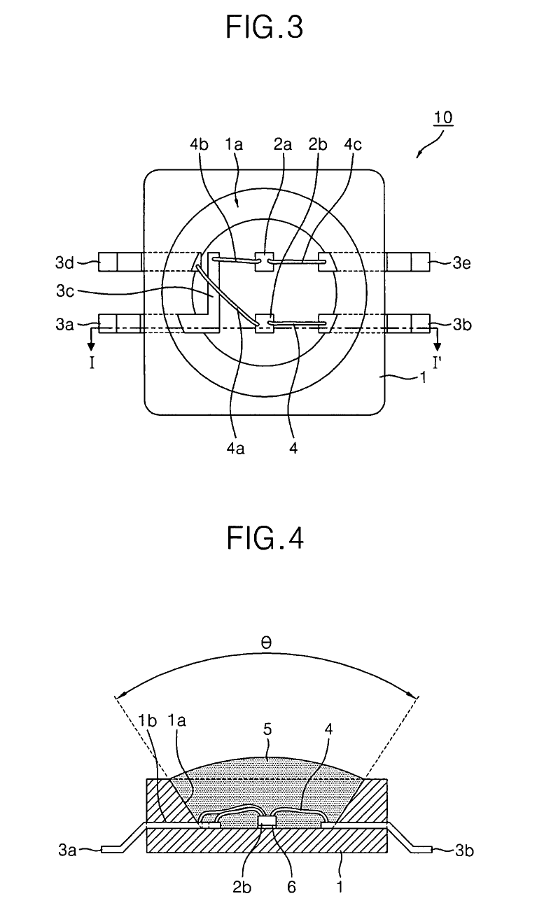

FIG. 3 is a plan view illustrating an LED package in accordance with an exemplary embodiment of the present invention, and FIG. 4 is a cross-sectional view taken along line I-I′ of FIG. 3. The LED package according to the exemplary embodiment of the present invention is described below with reference to FIGS. 3 and 4.

Referring to FIGS. 3 and 4, an LED package 10 includes a package substrate 1, first and second LED chips 2a and 2b, electrode terminals 3a, 3b, 3d, and 3e, electric wires 4, 4a, 4b and 4c, and a passivation member 5.

The package substrate 1 provides a space on which components of the LED package 10 are mounted. To this end, the package substrate 1 includes a light-emitting groove 1a and an electrode terminal hole 1b. The light-emitting groove 1a is hollow in a direction from a top of the package substrate 1 to a bottom thereof. The LED chips 2a and 2b are mounted at a central portion of the light-emitting groove 1a. The side of the light-emitting groove 1a has a slope. An angle of the slope determines a light-emitting angle at which light is emitted from the LED package 10. Preferably, the slop is formed to have a light-emitting angle θ of 105°. The light-emitting groove 1a of FIG. 3 has a circular shape, but is not limited thereto.

The electrode terminal hole 1b provides a space through which the electrode terminals 3a and 3b are inserted. One LED chip needs two electrode terminals, and thus the number of the electrode terminal holes 1b is twice as many as the number of the LED chips mounted on the package substrate 1. Preferably, the electrode terminal hole 1b is formed at the same height as the inside of the light-emitting groove 1a so that one end of each of the electrode terminals 3a and 3b inserted into the electrode terminal hole 1b can get closely stuck to the inside of the light-emitting groove 1a as shown in FIG. 4.

The package substrate 1 is made of a heat resistant material because the LED chips 2a and 2b mounted on the package substrate 1 generate heat a lot during a light-emitting process. Preferably, the package substrate 1 is made of polyphthalamide (PPA) resin. The PPA resin is advantageous because it is heat resistant and is rarely damaged by heat generated in the LED chips.

The LED chips 2a and 2b are mounted on the package substrate 1 to emit light. At least two LED chips which emit same color light are mounted on the package substrate 1.

A structure for mounting the two LED chips on one package substrate is first described below, and a structure for mounting three or more LED chips on one package substrate is described later.

In case where the two LED chips are mounted on a single package substrate, the two LED chips differ from each other in a brightness characteristic. The reason why the two LED chips having a different brightness are mounted on one package substrate is that the two LED chips having a different brightness together emit light of a mean brightness value of the two LED chips. In this instance, even though the two LED chips whose brightness difference is large are used, the brightness of the LED package is hardly different from that of another LED package. Accordingly, even though the LED chips having a different brightness are used for the LED package, the total brightness of each LED package becomes uniform. Thus, the LED chips having brightness characteristics of a broader range can be used, and therefore a ratio of the LED chips selected as a good quality product among fabricated LED chips is increased and a manufacturing cost of the LED chips is reduced.

For example, the first LED chip 2a has a higher brightness than the mean brightness value (m_{L}) obtained from the brightness test and the second LED chip 2b has a lower brightness than the mean brightness value (m_{L}). When the first and second LED chips 2a and 2b are mounted on the package substrate 1 together, the LED package 10 has a brightness close to the mean brightness value (m_{L}) because the brightness of the LED chip 2a and the brightness of the LED chip 2b are compensated with each other. Even though a brightness deviation of the LED chips is increased to 100 candela (“cd”) from existing 50 cd, a brightness deviation of the LED packages is less than 50 cd, and the LED package having a uniform brightness characteristic can be manufactured.

Each of the LED chips 2a and 2b is smaller in size than the conventional LED chip. The conventional LED chip has a size of 1 mm×1 mm. However, since a plurality of LED chips are mounted on one package substrate according to the present invention, even though the smaller LED chips are used, the LED package of the present invention shows the same brightness as the conventional LED chip. In one embodiment, each of the LED chips 2a and 2b of the present invention has a size of 450 μm×450 μm. Thus, the number of LED chips obtained from one wafer is increased compared to the conventional art, resulting in a low manufacturing cost.

In the LED package 10 of the present invention, the smaller LED chips than the conventional LED chips are arranged at a regular interval on the package substrate 1. The LED chips 2a and 2b generate a significant amount of heat during a light emitting process. Heat generated in the LED package 10 of the present invention is less than heat generated in the conventional LED package since the size of the LED chips is smaller than the conventional LED chips and the LED chips 2a and 2b are arranged to be apart from each at a regular interval. In the LED package 10 of the present invention, since positions where heat is generated are widely distributed, the generated heat is easily dispersed and externally released.

The LED chips 2a and 2b are mounted on the package substrate 1 by using an adhesive 6 as shown in FIG. 4. The adhesive 6 is made of a material having excellent thermal conductivity which can effectively release heat generated in the LED chips 2a and 2b. The adhesive 6 is made of thermal grease.

The electrode terminals 3a, 3b, 3d and 3e serve to apply an electrical power to the LED chips 2a and 2b. Each LED chip needs two electrode terminals as shown in FIGS. 3 and 4. Electrode terminals 3a and 3e supply electrical power to the first LED chip 2a and electrode terminals 3b and 3d supply electrical power to the second LED chip 2b. The electrode terminals 3a and 3b are inserted into the electrode terminal holes 1b, one end of each of the electrode terminals 3a and 3b is exposed inside the light emitting groove 1a and the other end of each of the electrode terminals 3a and 3b are exposed outside the package substrate 1.

The one end which is exposed inside the light-emitting groove 1a of the ends of the electrode terminals 3a and 3b is connected to the electric wire 4 by, for example, using a soldering technique. The other end which is exposed outside the package substrate 1 of the ends of the electrode terminals 3a and 3b is connected to an electric line formed on the circuit board. To this end, the other end is bent downwardly and arranged at the same height as the lower surface of the package substrate 1. Wires 4, 4a, 4b and 4c complete electrical connection from LEDs 2a and 2b to their associated terminals as illustrated in FIG. 3.

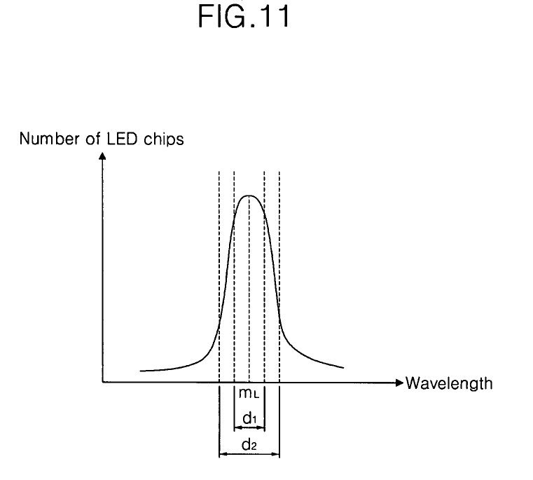

One of the electrode terminals 3a and 3b may comprise an extending portion, such as 3c which extends from the terminal 3a, which extends to cross the electric wire 4a which is connected to the electrode terminal 3d. The extending portion 3c is bent to be connected to the LED chip arranged at the more distant location of the LED chips through the electric wire 4. Thus, due to the extending portion 3c, as shown in FIG. 3, the electrode terminal 3a connected to the first LED chip 2a and electrode terminal 3d connected to the second LED chip 2b cross each other. In this instance, when a plurality of LED packages are mounted on the circuit board as shown in FIG. 10, the first LED chip 2a and the second LED chip 2b are alternately connected. That is, the first LED chip having a higher brightness and the second LED chip having a lower brightness are alternately connected by a single electric line. As a result, almost the same resistance is applied to each electric line, and a uniform electric current is applied to each LED chip.

Electrode terminal 3a having the extending portion 3c and electrode terminal 3d having no extending portion may be arranged at the same or different height on the light-emitting groove 1a. In the exemplary embodiment of the present invention, there is no need for a through process and an insulation processing process for crossing the electrodes on the circuit board since the electric lines are crossed on the LED package.

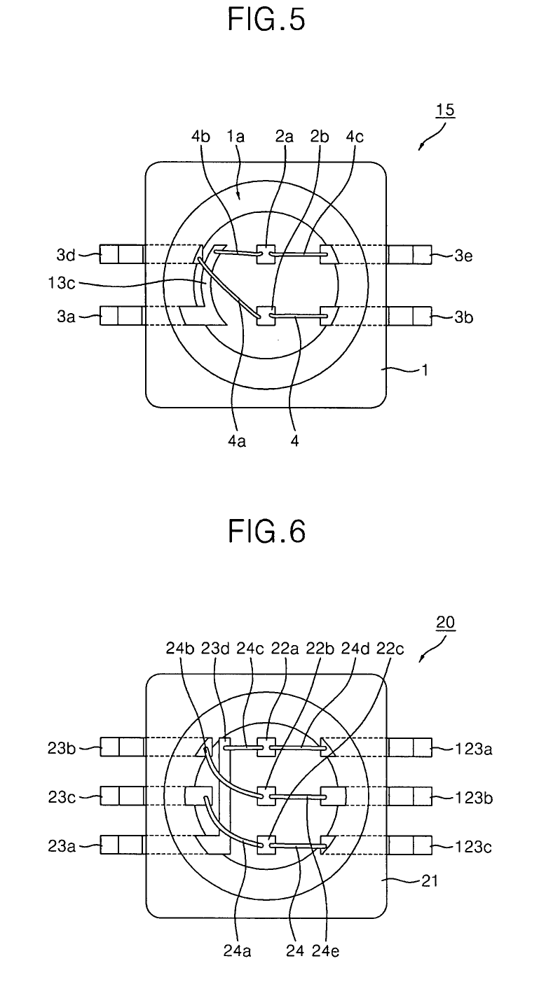

The extending portion 3c may alternatively be curved as shown in FIG. 5. FIG. 5 is a plan view illustrating an LED package 15 having a curved extending portion 13c according to another exemplary embodiment of the present invention. The extending portion 13c has a curvature corresponding to the shape of the light-emitting groove 1a. Thus, there is an advantage in that the LED chips can be easily mounted on the package substrate 1 having the small area size.

The electrode terminals 3a, 3b, 3d and 3e are preferably made of an alloy of nickel (Ni) and silver (Ag). The electrode terminals 3a, 3b, 3d and 3e made of an alloy of nickel (Ni) and silver (Ag) can be formed with a very thin thickness and have the excellent strength and electrical conductivity.

Wires 4, 4a, 4b and 4c electrically connect the inner ends of the electrode terminals to the LED chips 2a and 2b as shown in FIGS. 3 and 5. In the exemplary embodiment of the present invention, electric wires 4, 4a, 4b and 4c are electrically insulated from each other by the passivation member 5 which is described below. More particularly, passivation member 5 is interposed between the electric wires 4, 4a, 4b and 4c which cross each other, and thereby the electric wires are electrically insulated from each other. The electric wires 4, 4a, 4b and 4c are preferably made of gold (Au).

The passivation member 5 is formed on the package substrate 1 to cover the LED chips 2a and 2b and the electrode terminals 3a, 3b, 3d and 3e and protect the LED chips 2a and 2b and the electrode terminals. As shown in FIG. 4, the passivation member 5 fills the light-emitting groove 1a and covers the LED chips 2a and 2b and the inner ends of electrode terminals 3a, 3b, 3d and 3e as well as extending portion 3c. Since the LED chips 2a and 2b and the electrode terminals are not exposed, they are protected from any damage. The passivation member 5 is made of a light transmitting material through which light generated from the LED chips 2a and 2b can transmit to the external portion. Suitable materials for passivation member 5 may be transparent soft epoxy resin. In order to obtain white light, the passivation member 5 may be made of an illuminant material for generating a different color from a color of light generated by LED chips 2a and 2b. That is, the white light can be obtained by mixing the color of light generated from the LED chips 2a and 2b and the color of the passivation member 5. For example, when the LED chips 2a and 2b mounted on the package substrate 1 generate blue light, the passivation member 5 has the yellow color. Thus, the white light may be easily obtained by the LED chips 2a and 2b and the passivation member 5 by employing this simple structure.

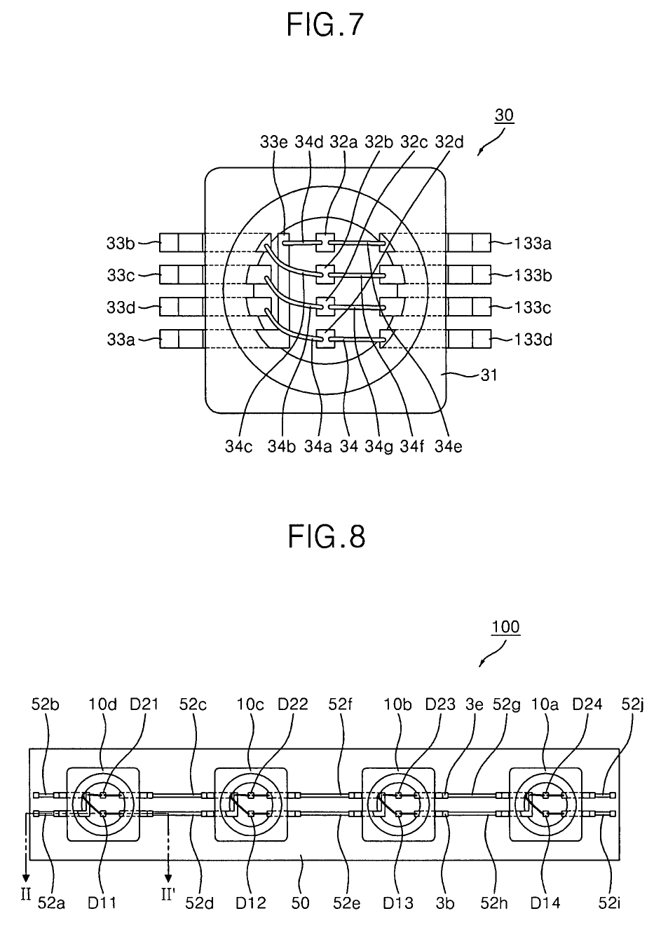

A case where three LED chips are mounted on one package substrate and a case where four LED chips are mounted on one package substrate are described below with reference to FIGS. 6 and 7. FIG. 6 is a plan view illustrating an LED package in which three LED chips are mounted on one package substrate, and FIG. 7 is a plan view illustrating an LED package in which four LED chips are mounted on one package substrate.

Referring to FIG. 6, three LED chips 22a, 22b and 22c are mounted on a package substrate 21. The three LED chips 22a, 22b and 22c generate the same color light but have a different brightness. For example, the LED chip 22a has a higher brightness than the mean brightness value (m_{L}), the LED chip 22b has a lower brightness than the mean brightness value (m_{L}), and the LED chip 22b has a brightness equal or close to the mean brightness value (m_{L}). Even when three LED chips 22 having different brightness characteristics are mounted on one package substrate 21, the average brightness of an LED package 20 is close to the mean brightness value (m_{L}), thereby obtaining the LED package 20 having a uniform brightness.

In the LED package 20 having the three LED chips 22a, 22b, and 22c, one of electrode terminals 23a, 23b and 23c respectively connected to the LED chips 22a, 22b, and 22c has an extending portion 23d to cross the two remaining electrode terminals 23b and 23c as shown in FIG. 6. Preferably, electric wire 24c connected to the LED chip 22a arranged at the top is connected to the electrode terminal 23a arranged at the bottom via the extending portion 23d.

In FIG. 6, the three LED chips 22a, 22b, and 22c are arranged in a line. However, the three LED chips 22a, 22b, and 22c may be arranged in various forms such as a triangle. LED chips 22a, 22b, and 22c are preferably arranged in a spaced apart relationship to more effectively release generated heat.

The other components of the LED package of FIG. 6 are substantially same as that of FIGS. 3 and 4, and thus duplicated description is omitted.

FIG. 7 illustrates an LED package 30 in which four LED chips 32a, 32b, 32c, and 32d are arranged on one package substrate 31. The four LED chips 32a, 32b, 32c, and 32d are arranged in a line, but they may be arranged in various forms such as a rectangle. One of four electrode terminals 33a, 33b, 33c, and 33d has an extending portion 33e to cross the remaining three of the electrode terminals 33b, 33c, and 33d. Wires 34, 34a, 34b, 34c, 34d, 34e, 34f and 34g connect the LEDs to the electrode terminals associated with the LEDs.

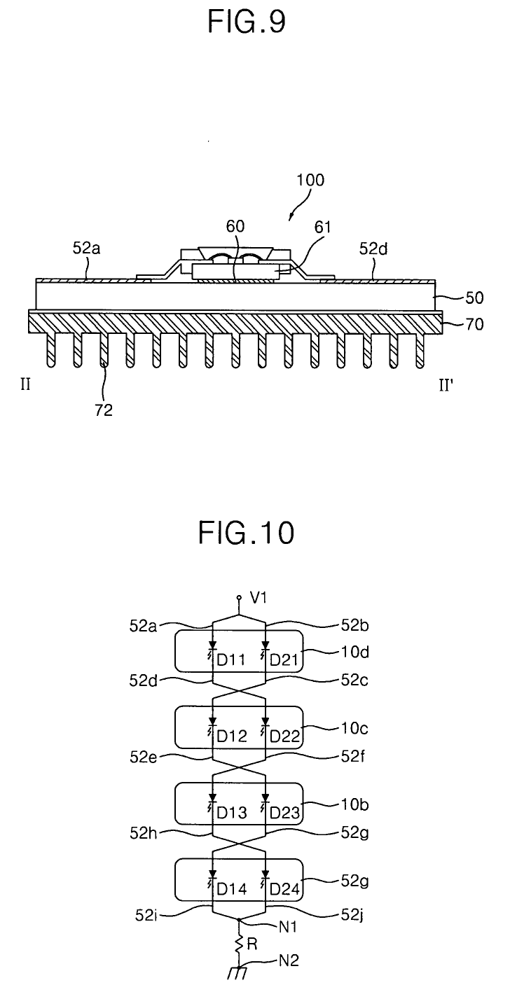

A backlight unit according to an exemplary embodiment of the present invention is described below with reference to FIGS. 8 and 9. FIG. 8 is a plan view illustrating the backlight unit 100 in accordance with the exemplary embodiment of the present invention, and FIG. 9 is a cross-sectional view taken along line II-II′ of FIG. 8.

Referring to FIG. 8, a backlight unit 100 of the present invention comprises a circuit board 50 and a plurality of LED packages 10a, 10b, 10c, and 10d. The circuit board 50 provides a space on which the LED packages 10a, 10b, 10c, and 10d are mounted. In the circuit board 50, electric lines 52a-52j which are electrical conductors provide electrical power to the LED packages 10a, 10b, 10c, and 10d are also mounted. The electric lines are preferably made of copper (Cu) and are formed in a thin film form. The electric lines 52a-52j are electrically connected to the electrode terminals of the LED packages by using a soldering technique, for example. In the exemplary embodiment of the present invention, since two LED chips are mounted in one LED package, two rows of electric lines are used. A distance between the two electric lines, for example segments 52d and 52c, is substantially same as a distance between the two electrode terminals, for example 3b and 3e as shown in FIG. 5. Because the wiring inside of the LED packages 10a, 10b, 10c and 10d are crossed, when the LED packages 10a, 10b, 10c and 10d are mounted on the circuit board 50 and connected to the line segments 52I to 52J, the LED chips are connected in a crisscross fashion.

The other components of the LED packages used in the backlight unit are same as described above, and thus duplicated description is omitted.

Referring to FIG. 9, the backlight unit 100 may further comprise a heat slug 60 arranged between the package substrate 61, and the circuit board 50. The heat slug 60 serves to fix the LED package 10d to the circuit board 50 and to transfer heat generated in the LED chips to the circuit board 50. The heat slug 60 is preferably made of a material having excellent heat transfer characteristics such as lead-free materials.

The backlight unit 100 may further comprise a heat plate 70 arranged on the back surface of the circuit board 50. The heat plate 70 serves to effectively release the heat transferred via the heat slug 60 to circuit board 50. The heat plate 70 may have a plurality of heat releasing pins 72 in order to increase its surface area.

The backlight unit 100 may further comprise a current detecting resistor R as shown in FIG. 10. FIG. 10 is a circuit diagram illustrating the backlight unit in accordance with an exemplary embodiment of the present invention. Ends of the electric lines 52i and 52j are commonly connected at a node N1. A current detecting resistor R is connected to the node N1 for connecting the LED packages. The current detecting resistor R detects the magnitude of the electric current supplied to the LED package and limits the electric current.

In the present invention, a plurality LED chips of which brightness values are much different from the mean brightness value (m_{L}) are used to compensate each other, and thus an LED package comprising the LED chips can have a uniform brightness characteristic. Accordingly, LED chips having a wide range of brightness values can be used in the LED package. That is, as shown in FIG. 11, a brightness range d2 of the LED chips used in the present invention is broader than a brightness range d1 of the conventional art.

As described above, the ratio of usable LED chips to the fabricated LED chips is increased, and thus the manufacturing cost of a backlight assembly using the LED chips is reduced.

Also, since LED chips smaller than the conventional LED chips are used, the heat generated during the light-emitting process is reduced, and since the LED chips can be arranged at a large interval, the heat is easily dispersed and released.

Further, since the internal wires connecting the LED chips in the packages are crossed, there is no need for crossing the electric lines on the circuit board.

While the invention has been shown and described with reference to a certain preferred embodiment thereof, it will be understood by those skilled in the art that various changes in form and details may be made therein without departing from the spirit and scope of the invention as defined by the appended claims.

What is claimed is:

1. A light-emitting diode (LED) package, comprising:
a substrate;
at least two LED chips arranged on the substrate in a spaced apart relationship, the at least two chips having different brightness characteristics;
a plurality of electrode terminals mounted on the substrate to supply electrical power to the at least two LED chips; and
electrical conductors connecting the electrode terminals to the at least two LED chips.

2. The LED package of claim 1, wherein the at least two LED chips emit the same color light.

3. The LED package of claim 1, wherein the at least two LED chips comprise: a first LED chip having a brightness greater than a mean brightness value; and a second LED chip having a brightness less than the mean brightness value.

4. The LED package of claim 1, wherein the plurality of electrode terminals includes first, second, third and fourth terminals, and the electrical conductors include first, second, third and fourth electrical conductors, the first and second electrode terminals are coupled to the first and second electrical conductors for supplying electrical power to one of the at least two LED chips, and the third and fourth electrode terminals are coupled to the third and fourth electrical conductors for supplying electrical power to the other LED chip.

5. The LED package of claim 4, wherein the at least one of the first and second electrode terminals associated with one of the first and second LED chips has an extending portion which extends such that it insulatedly crosses a path of an electrical conductor connected to the other one of the LED chips.

6. The LED package of claim 1, further comprising a passivation member arranged on the substrate to cover the LED chips.

7. The LED package of claim 6, wherein the passivation member is made of a light transmitting material.

8. The LED package of claim 6, wherein the passivation member is made of an illuminant material.

9. The LED package of claim 8, wherein the passivation member is made of the illuminant material generating a different color from a color of light generated from the LED chips.

10. A backlight unit, comprising:
a circuit board having formed thereon first and second electrical conductors; and
a plurality of light-emitting diode (“LED”) packages mounted on the circuit board, each electrically connected to the first and second electrical conductors,
each LED package comprising:
a substrate;
at least two LED chips mounted on the substrate in a spaced apart relationship, the at least two chips having different brightness characteristics;
a plurality of electrode terminals mounted on the substrate to supply electrical power to the at least two LED chips; and
electrical conductors connecting the electrode terminals to the at least two LED chips.

11. The backlight unit of claim 10, wherein the at least two LED chips emit the same color light.

12. The backlight unit of claim 11, wherein the at least two LED chips comprise: a first LED chip having a brightness greater than a mean brightness value; and a second LED chip having a brightness less than the mean brightness value.

13. The backlight unit of claim 12, wherein the plurality of electrode terminals includes first, second, third and fourth terminals, and the electrical conductors include first, second, third and fourth electrical conductors, the first and second electrode terminals are coupled to the first and second electrical conductors for supplying electrical power to one of the at least two LED chips, and the third and fourth electrode terminals are coupled to the third and fourth electrical conductors for supplying electrical power to the other LED chip.

14. The backlight unit of claim 13, wherein the at least one of the first and second electrode terminals associated with one of the first and second LED chips has an extending portion which extends such that it insulatedly crosses a path of an electrical conductor connected to the other one of the LED chips.

15. The backlight unit of claim 10, further comprising a passivation member arranged on the package substrate to cover the LED chips.

16. The backlight unit of claim 15, wherein the passivation member is made of an illuminant material generating a different color from a color of light generated from the LED chips.

17. The backlight unit of claim 10, further comprising a heat slug positioned between at least one LED package substrate and the circuit board.

18. The backlight unit of claim 17, further comprising a heat sink positioned on a side of the circuit board opposite the side of the circuit board on which the LED packages are positioned.

19. The backlight unit of claim 18, wherein ends of the first and second electrical conductors are commonly connected at a node.

20. The backlight unit of claim 19, further comprising a current detecting resistor electrically connected to the node.
